(19) United States
(12) Patent Application Publication
(10) Pub. No.: US 2017/0082918 A1
(43) Pub. Date: Mar. 23, 2017

(54) TEMPLATE, IMPRINT DEVICE, AND CONTROL METHOD

(71) Applicant: Kabushiki Kaisha Toshiba, Minato-ku (JP)

(72) Inventor: Tetsuya KUGIMIYA, Kawasaki (JP)

(73) Assignee: Kabushiki Kaisha Toshiba, Minato-ku (JP)

(21) Appl. No.: 15/257,121

(22) Filed: Sep. 6, 2016

(30) Foreign Application Priority Data
Sep. 17, 2015 (JP) 2015-184179

(51) Int. Cl. G03F 1/50; G03F 7/00; H01L 21/67

(52) U.S. Cl. CPC G03F 1/50; H01L 21/6715; G03F 7/0002

(57) ABSTRACT

A template for imprinting according to an embodiment configured to be pressed onto a semiconductor wafer to transfer thereto a pattern, and may include an imprint mask on which the pattern is formed, a photomask substrate on which the imprint mask is provided, and a plurality of deformation controllers that are provided at the photomask substrate outside a circumference of the imprint mask, and are configured to deform the photomask substrate.

### CROSS-REFERENCE TO RELATED APPLICATIONS

This application is based upon and claims the benefit of priority from Japanese Patent Application No. 2015-194179, filed on Sep. 17, 2015; the entire contents of which are incorporated herein by reference.

### FIELD

Embodiments described herein relate generally to a template, an imprint device, and a control method.

### BACKGROUND

Heretofore, as the size of semiconductor devices has decreased, the pattern width thereof has decreased. As a result, the resolution of pattern transfer using light is beginning to be insufficient. Hence, in recent years, imprint technology has begun to be used as a substitute for the pattern transfer using light.

The imprint technology is a technique in which an imprint mask with an asperity pattern formed thereon is pressed onto an imprint material applied on a wafer substrate, and the imprint material is solidified in that state so as to transfer the asperity pattern of the imprint mask onto the wafer substrate to form the pattern thereon. Conventional techniques are described in, for example, Japanese Laid-open Patent Publication No. 2013-219230, Japanese Laid-open Patent Publication No. 2013-096291, Japanese Laid-open Patent Publication No. 2015-029070, and Japanese Translation of PCT International Application Publication No. 2009-536591.

### BRIEF DESCRIPTION OF THE DRAWINGS

FIG. 1 is a schematic sectional view illustrating a schematic configuration example of a template according to a conventional technique;

FIG. 2 is a schematic diagram for explaining an operation to press the template onto a wafer;

FIG. 3 is a diagram for explaining full imprint regions and partial imprint regions formed by one imprinting step;

FIG. 4 is a top view illustrating a schematic configuration example of a template according to a first embodiment;

FIG. 5 is a sectional view taken along A-A illustrated in FIG. 4;

FIG. 6 is a diagram illustrating a positional relation between the center of an imprint mask and an apex P of deformation when the template according to the first embodiment has been convexly deformed;

FIG. 7 is a diagram illustrating the positional relation between the center of the imprint mask and the apex P of deformation when the apex P of deformation according to the first embodiment has been shifted;

FIG. 8 is a flowchart illustrating an operation example during a pattern transfer according to the first embodiment;

FIG. 9 is a flowchart illustrating an example of an operation to perform higher-order correction of distortion of the imprint, mask according to the first, embodiment;

FIG. 10 is a schematic sectional view illustrating a schematic configuration example of a template according to a second embodiment;

FIG. 11 is a schematic sectional view illustrating the schematic configuration example of the template according to the second embodiment when being subjected to a higher-order distortion;

FIG. 12 is a schematic sectional view illustrating part extracted from a schematic configuration example of a template according to a third embodiment;

FIG. 13 is a diagram for explaining a first mode according to the third embodiment;

FIG. 14 is a diagram for explaining a second mode according to the third embodiment;

FIG. 15 is a schematic diagram illustrating a schematic configuration example of an imprint device in a fourth embodiment; and

FIG. 16 is a schematic diagram illustrating another schematic configuration example of the imprint device in the fourth embodiment.

### DETAILED DESCRIPTION

The following describes in detail a template, an imprint device, and a control method according to exemplary embodiments, using the drawings.

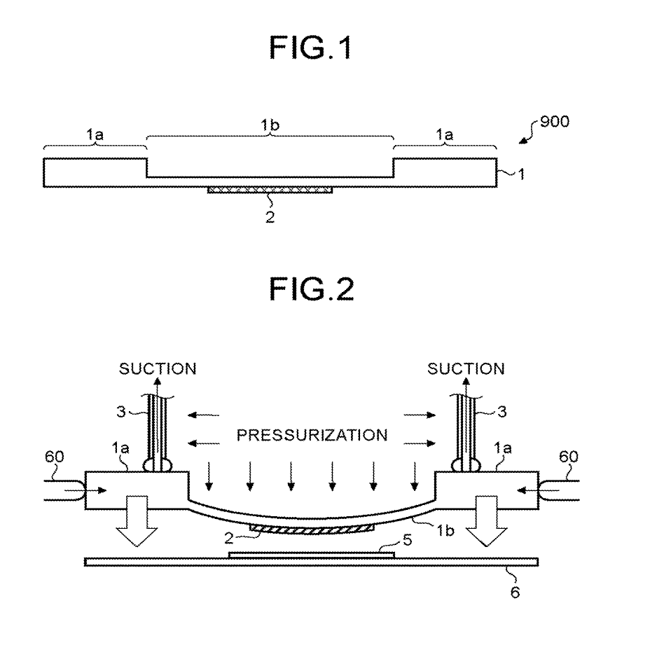

To transfer patterns onto a wafer using a general imprint lithography technique, a template 900 is used and includes a photomask substrate 1 and an imprint mask 2 that is placed at the center of a first surface (serving as the lower surface) of the photomask substrate 1 and has mask patterns for one shot formed on the imprint mask 2, as illustrated in FIG. 1. The central portion of a second surface (serving as the upper surface) of the photomask substrate 1 is processed into a thin circular form so as to form a counterbore structure. Accordingly, the photomask substrate 1 is constituted by a thick portion 1a at the outer circumferential portion thereof and a thin portion 1b at the central portion thereof. The thin portion 1b is slightly larger in size than the imprint mask 2, and the imprint mask 2 is placed at the center on the lower surface of the thin portion 1b so as not to protrude from the thin portion 1b.

When the patterns are transferred, a circular cylindrical vacuum chuck 3 sucks the upper surface of the thick portion 1a to hold the template 900, as illustrated in FIG. 2. An interior space formed by the template 900 and the vacuum chuck 3 is pressurized. This pressure deforms the thin portion 1b toward the lower surface to produce a convex curvature of the imprint mask 2. The imprint mask 2 thus convexly deformed is pressed onto a wafer 6 with a resist liquid 5 applied thereto so that the resist liquid 5 spreads over without producing air bubbles in gaps formed by asperity of the imprint mask 2. In this state, the photo-curable resist liquid 5 is irradiated with light to be hardened, and then, the template 900 is moved upward to be separated from the wafer 6. This process transfers the patterns of the imprint mask 2 onto the wafer 6. In the following description, a term “imprinting step” is used to refer to the step from the pressing of the imprint mask to the wafer via optical exposure until the separation of the imprint mask from the wafer.

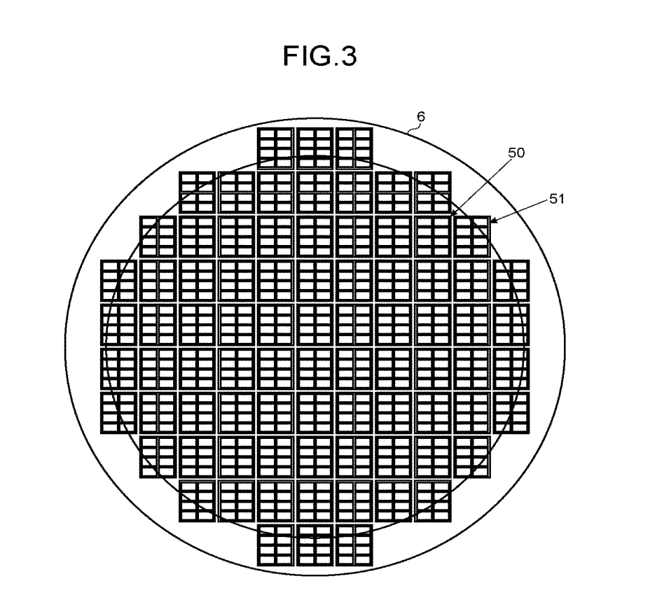

While the imprinting step transfers the patterns onto the wafer 6 having a pattern forming area in which a plurality of pattern regions are formed, cases occur where one imprinting step is not sufficient to transfer the patterns onto all the pattern regions. In those cases, the wafer 6 is provided with pattern regions (hereinafter, called full imprint regions) 50 formed thereon to which patterns have been fully transferred in one imprinting step and pattern regions (hereinafter, called partial imprint regions) 51 formed thereon to which patterns have not been fully transferred in one imprinting step, as illustrated in FIG. 3. The partial imprint regions 51 are usually located near a peripheral portion of the wafer 6.

The patterns are transferred onto the partial imprint. regions 51, for example, by adjusting the positional relation between the wafer 6 and the template 900, and performing the imprinting step again. However, in the case of convexly deforming the template 90 by applying the pressure during the imprint to the wafer 6 as described above, the apex of the deformation is located substantially at the center of the imprint mask 2. Due to this, in the step of imprinting the partial imprint regions 51, the adjustment of the positional relation may cause the apex of the deformation to deviate from the pattern forming area of the wafer 6, in some cases. In such cases, when the imprint mask 2 is pressed onto the wafer 6, a portion other than the apex of the deformation of the imprint mask 2 may first come into contact with the wafer 6, and this may cause, for example, a step at an end of the wafer 6 or a corner of the wafer 6 to locally come into contact with the imprint mask 2 to produce a scratch or the like on the imprint mask 2. The damage of the imprint mask 2 thus produced reduces the life of the template 900, and is therefore desired to be avoided.

A method for avoiding the damage of the imprint mask 2 can be considered in which the wafer 6 is imprinted while the template 900 is inclined. Even in this case, however, the corner or like of the template 900 may come into contact with the wafer 6, so that a limitation is placed on the rotation angle for inclining the template 900. This causes a problem in that the method does not effectively work for all the partial imprint regions 51 in some cases.

In the production of semiconductor devices using the imprint technology, the same type or a different type of new patterns need to be formed on the patterns previously formed on the wafer 6, in some cases. Such a series of pattern forming steps requires high accuracy of position alignment between the new and old sets of patterns. However, the position of the imprint mask 2 provided on the template 900 includes a deviation from a design position, and the positions of the patterns formed on the wafer 6 are deviated from design positions due to the deformation of the wafer 6. Thus, the sets of patterns are difficult to be accurately aligned in position.

First-order components of positional deviations produced between the sets of patterns can be corrected, for example, by urging the side surface of the photomask substrate 1 with actuators 60 or the like from a plurality of directions, as illustrated in FIG. 2. Such a method enables lower-order distortion correction, such as linear correction. However, higher-order deformations are difficult to be produced in the imprint mask 2, so that the method does not enable higher-order distortion correction, which is a problem.

Accordingly the following describes, by way of some embodiments, a template, an imprint device, and a control method that enable prevention of reduction in the life of the imprint mask 2 and the higher-order distortion correction of the imprint mask 2.

### First embodiment

First, a template, an imprint device, and a control method according to a first embodiment will be described using some drawings. The template according to the first embodiment has a structure that deforms the photomask substrate around the imprint mask. With the imprint device including the template and the control method of the imprint device, an amount of expansion or an amount of contraction of a structure for deforming the photomask substrate is controlled so as to control the position of the apex of the imprint mask. This control enables moving of a portion of the template first coming into contact with the wafer during the imprint, and thereby can avoid corners at wafer ends from locally coming into contact with the imprint mask in the step of imprinting the partial imprint regions. As a result, the imprint mask can be prevented from being damaged, and the life of the template can be consequently prevented from decreasing.

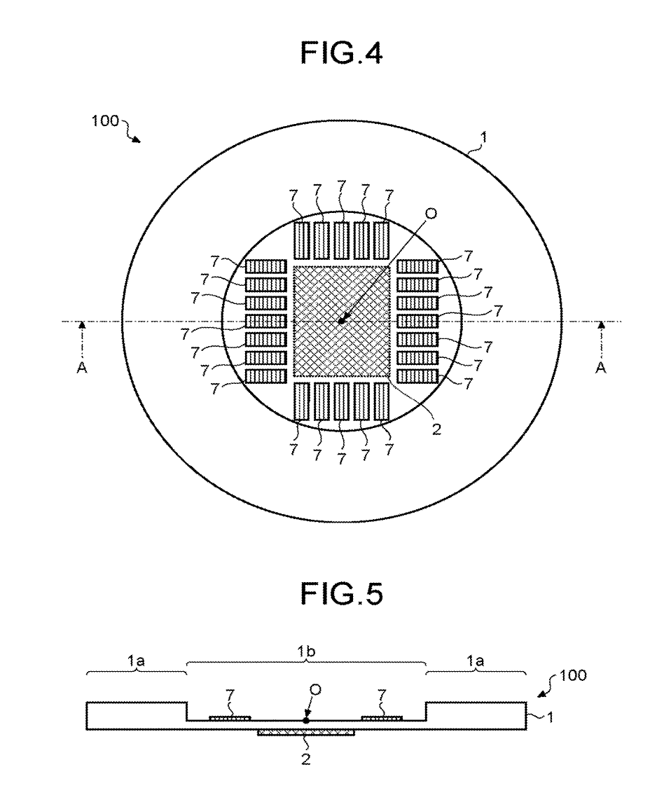

FIG. 4 is a top view illustrating a schematic configuration example of the template according to the first embodiment. FIG. 5 is a sectional view taken along A-A illustrated in FIG. 4. As illustrated in FIGS. 4 and 5, a template 100 includes the photomask substrate 1 and the imprint mask 2 that are the same as those in the template 900 illustrated in FIG. 1, and also includes a plurality of deformation members 7 serving as deformation controllers for deforming the photomask substrate 1.

The photomask substrate 1 is made of, for example, glass or synthetic quartz, and has the configuration in which the counterbore structure is provided at the central portion of the plate-like transparent substrate, as described above. The imprint mask 2 is placed at the center on the lower surface of the thin portion 1b of the photomask substrate 1 so as not to protrude from the thin portion 1b.

Each of the deformation members 7 is made of a member controllable in expansion or contraction, such as a thin-film like piezoelectric element (hereinafter, called a piezoelectric thin film). The deformation members are provided on the thin portion 1b that can be relatively easily deformed. The deformation members 7 are provided at places outside the circumference of the imprint mask 2 so as to surround the imprint mask 2 so as not to block light during the optical exposure. Although the deformation members 7 are provided on the upper surface of the thin portion 1b in FIG. 5, the deformation members 7 may be provided on the lower surface of the thin portion 1b. If the deformation members 7 are provided on the lower surface of the thin portion 1b, that is, on the same surface as that provided with the imprint mask 2, the deformation members 7 desirably have a thickness smaller than the thickness of the imprint mask 2. As illustrated in FIG. 4, the deformation members 7 are arranged so as to be symmetrical with respect to a point O that lies on the upper surface of the thin portion 1b and corresponds to the center of the imprint mask 2, or so as to be point-symmetric or axisymmetric with respect to a line passing through the point O and parallel to the upper surface of the thin portion 1b.

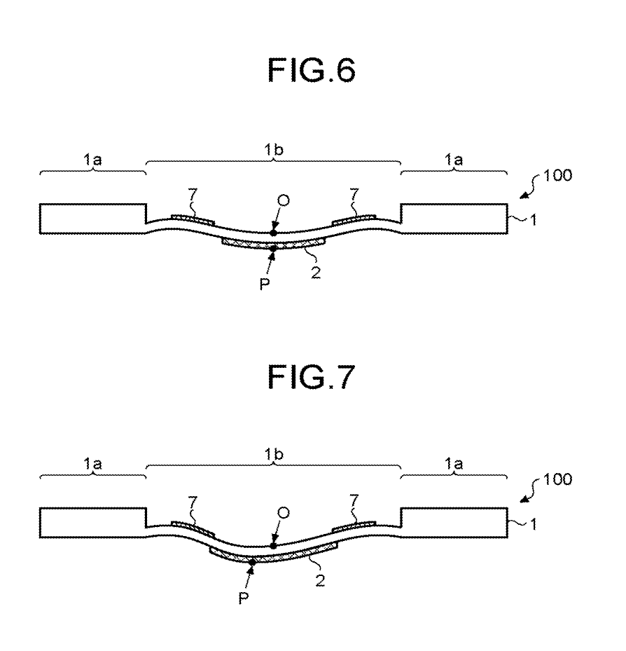

If the deformation members 7 are controlled so that the amounts of expansion or contraction of the individual deformation members are symmetrical with respect to the point O corresponding to the center f the imprint mask 2, the template 100 having the structure described above can be deformed so that the center of the imprint mask 2 becomes the apex P, as illustrated in FIG. 6.

If, instead, the deformation members 7 are controlled so that the amounts of expansion or contraction of the individual deformation members 7 are asymmetrical with respect to the point O, the apex P of deformation can be formed at a location different from the center of the imprint mask 2, as illustrated in FIG. 7. Accordingly, in the first embodiment, the position of the apex P is adjusted by controlling the deformation members 7 so that the apex P of deformation does not deviate from the pattern forming area of the wafer 6 when the partial imprint regions 51 are imprinted. This adjustment allows the patterns to be sequentially imprinted from a portion in the pattern forming area with which the apex P comes into contact. The higher-order correction of distortion of the imprint mask can be performed by individually controlling the deformation members 7 while the wafer is imprinted.

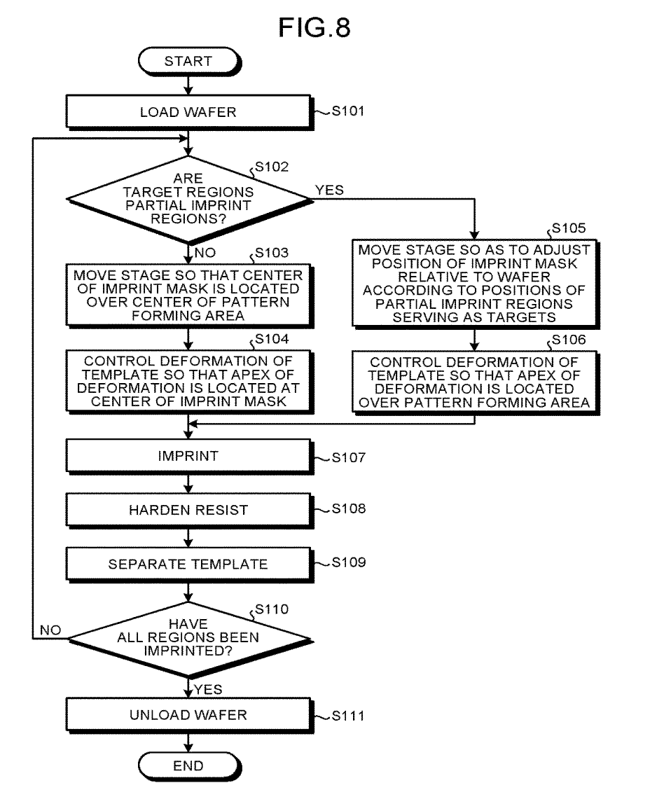

The following describes in detail an operation during the pattern transfer according to the first embodiment using FIG. 8. FIG. 6 is a flowchart illustrating an operation example during the pattern transfer according to the first embodiment. FIG. 8 illustrates an operation of a controller for controlling an imprint lithography device equipped with the template 100 according to the first embodiment.

As illustrated in FIG. 8, in the present operation, the controller first loads the wafer 6 on a predetermined stage (Step S101). The controller then determines whether pattern regions serving as a pattern transfer target are the partial imprint regions 51 (Step S102). The controller performs processing at Step S103 if the target regions are not the partial imprint regions 1 (No at Step S102), or performs processing at Step S105 if the target regions are the partial imprint regions 51 (Yes at Step S102).

A Step S103, the controller moves the stage loaded with the wafer 6 so that the center of the imprint mask 2 is located over the center of the pattern forming area on the wafer 6. The controller subsequently controls the deformation members 7 so that the apex P of deformation coincides with the center of the imprint mask Step S104), and performs processing at Step S107.

At Step S105, the controller moves the stage so adjust the position of the wafer 6 relative to the imprint mask 2 according o the positions of the partial imprint regions serving as the targets on the wafer 6. The controller subsequently controls the deformation members 7 so that the apex P of deformation is located over the pattern forming area on the wafer 6 (Step S106), and performs the processing at Step S107.

The controller then presses the imprint mask 2 onto the wafer 6 by moving down the template 100 toward the wafer 6 (Step S107), and, in that state, irradiates the resist liquid 5 on the wafer 6 with light so as to harden the resist liquid 5 (Step S108). The controller then moves up the template 100 so as to separate the template 100 from the wafer 6 (Step S109).

The controller then determines whether the pattern transfer (imprinting) has been completed for all the pattern regions in the pattern forming area on the wafer 6 (Step S110). If so (Yes at Step S110), the controller unloads the wafer 6 from the stage (Step S111), and ends the present operation. If not (No at Step S110), the controller returns the process to Step S102, and performs the subsequent operation again.

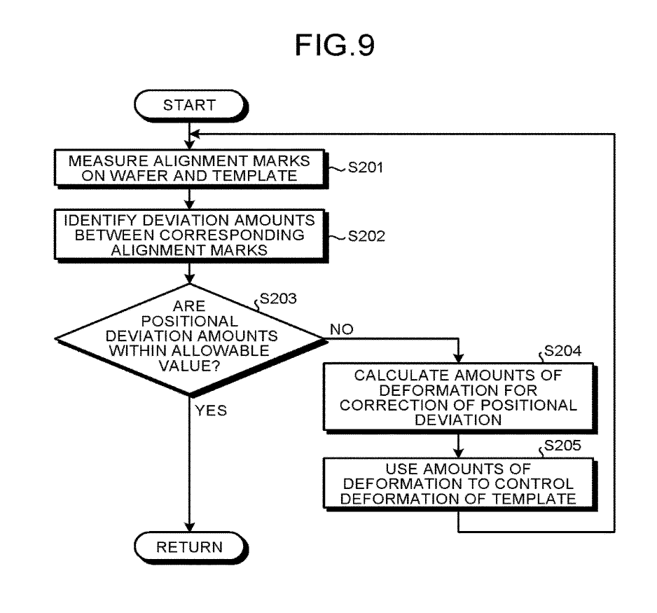

The following describes in detail a case in which the operation during the pattern transfer illustrated in FIG. 8 includes an operation to perform the higher-order correction of distortion of the imprint mask 2, using FIG. 9. FIG. 9 is a flowchart illustrating an example of the operation to perform the higher-order correction of distortion of the imprint mask according to the first embodiment. FIG. 9 illustrates the operation of the controller in the same manner as FIG. 8.

The operation illustrated in FIG. 9 is performed, for example, subsequently to Step S107 in FIG. 8. That is, after moving down the template 100 and pressing the imprint mask 2 onto the wafer 6, the controller uses a charge-coupled device (CCD) camera or the like to measure alignment marks for position alignment provided in advance on the wafer 6 and alignment marks for position alignment provided in advance on the template 100 (Step S201), and identifies, from the measured positions of the alignment marks, amounts of positional deviation (positional deviation amounts) in the respective positions (Step S202). The alignment marks are provided in advance in a predetermined array or at predetermined intervals on both the pattern regions of the wafer 6 and the imprint mask 2. The alignment marks may have a particular shape, such as a groove shape or a convex shape. A wiring pattern of a certain shape may be used as the alignment marks on the wafer 6.

Then, the controller determines whether the identified positional deviation amounts of the alignment marks are within a predetermined allowable range (Step S203). If so (Yes at Step S203), the controller returns the process to the operation illustrated in FIG. 8, and performs Step S108 and later processes. If not (No at Step S203), the controller calculates amounts of deformation of the deformation members 7 necessary for correction to reduce the positional deviation amounts into the allowable range (Step S204), and uses the calculated amounts of deformation to control the deformation of the template 100 (Step S205). The controller then returns the process to Step S201, and performs the subsequent operations again.

As described above, according to the first embodiment, the position of the apex P of the imprint mask 2 during the convex deformation can be controlled by controlling the deformation members 7. This control can avoid corners at ends of the wafer 6 from locally coming into contact with the imprint mask in the step of imprinting the partial imprint regions 51, and as a result, can prevent the life of the template from decreasing.

According to the first embodiment, the higher-order correction of the positional deviation between the imprint mask 2 and the pattern regions on the wafer 6 can be performed by individually controlling the deformation members 7 in the state in which the imprint mask 2 is pressed onto the wafer 6.

### Second embodiment

The following describes a template, an imprint device, and a control method according to a second embodiment, using some drawings. While the first embodiment has exemplified the case in which the deformation members 7 are provided on one of the upper and lower surfaces of the thin portion 1b of the photomask substrate 1, the second embodiment will exemplify a case in which deformation members are provided on both the upper and lower surfaces of the thin portion 1b.

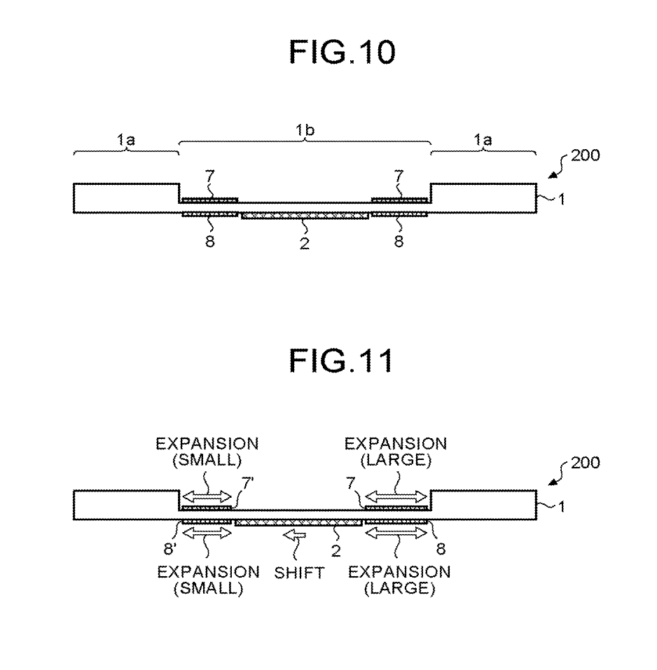

FIG. 10 is a schematic sectional view illustrating a schematic configuration example of a template according to the second embodiment. The section illustrated in FIG. 10 is a section corresponding the A-A section of the template 100 illustrated in FIG. 4. The top view of the template according to the second embodiment may be the same as the top view of the template 100 illustrated as FIG. 4, so that FIG. 4 will be referred to in the second embodiment.

As illustrated in FIG. 10, a template 200 has, in addition to the same configuration as that of the template 100 according to the first embodiment, a configuration in which a surface (lower surface in FIG. 10) of the thin portion 1b opposite to the deformation members 7 is provided with a plurality of deformation members 8 each constituting a deformation controller for deforming the photomask substrate 1 by forming a pair with corresponding one of the respective deformation members 7.

Each of the deformation members 8 is made of a member controllable in expansion or contraction, such as a piezoelectric thin film, in the same manner as the deformation member 7. Accordingly, the higher-order distortion correction of the imprint mask 2 can be performed without producing a curvature deformation of the template 200 by giving the deformation members 8 and 7 forming pairs with the thin portion 1b interposed therebetween the same amount of expansion or contraction. For example, as illustrated in FIG. 11, a set of deformation members 7 and 7′ and a set of deformation members 8 and 8′ are arranged on the upper and lower surfaces of the thin portion 1b so as to form pairs with the thin portion 1b interposed therebetween and so as to surround the imprint mask 2. A set of deformation members 7 and 8 located on the opposite side with the thin portion 1b interposed therebetween are given substantially the same expansion or contraction as each other. In the same manner, the deformation members 7′ and 8′ are given substantially the same expansion or contraction as each other. By doing this, a partial expansive or contractive deformation can be given without producing a curvature deformation of the template 200, and a stress for partially shifting the imprint mask 2 can be produced by giving a set of deformation members 7 and 8 and a set of deformation members 7′ and 8′ different amounts of expansion or contraction from each other. The set of deformation members 7′ and 8′ located on the opposite side of the set of deformation members 7 and 8 with the imprint mask 2 interposed therebetween need not be necessarily given a relatively smaller expansion than the set of deformation members 7 and 8 given a relatively large expansion as illustrated in FIG. 11. The set of deformation members 7′ and 8′ may be given a contraction, or may be given neither the expansion nor the contraction.

The position of the apex F of the imprint mask 2 during the convex deformation can be controlled in the same manner as in the first embodiment by giving the deformation members 7 and 8 forming a pair with the thin portion 1b interposed therebetween different amounts expansion or contraction from each other. This approach can avoid corners at ends of the wafer 6 from locally coming into contact with the imprint mask in the step of imprinting the partial imprint regions 51, and as a result, can prevent the life of the template from decreasing.

Other configurations, operations, and effects are the came as those of the other embodiments, so that detailed descriptions thereof are omitted here.

### Third Embodiment

The following describes in detail, as a third embodiment, another configuration that enables the higher-order distortion correction of the imprint mask without producing a curvature deformation of a template, using some drawings.

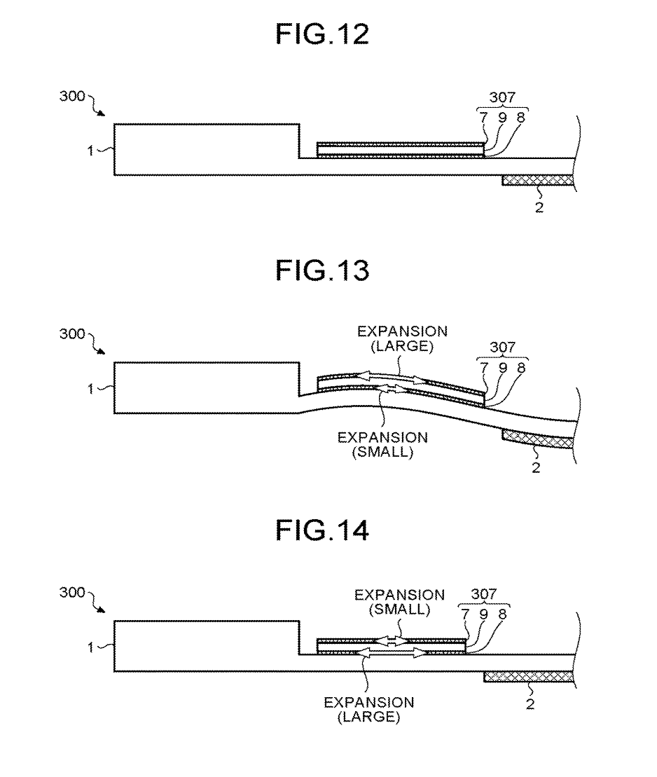

FIG. 12 is a schematic sectional view illustrating a part extracted from a schematic configuration example of a template according to the third embodiment. FIG. 1 illustrates a structure of a section corresponding to the A-A section of the template 100 illustrated in FIG. 4, and is a view focusing on the structure in the vicinity of one of the sides of the thick portion 1a at both ends. The top view of the template according to the third embodiment, may be the same as the top view of template 100 illustrated in FIG. 4, so that FIG. 4 will be referred to in the third embodiment.

As illustrated in FIG. 12, a template 300 has a configuration obtained by replacing the deformation members 7 with a plurality of deformation controllers 307 in the same configuration as the template 100 according to the first embodiment. Each of the deformation controllers 307 has configuration in which the deformation members 7 and 8 controllable in expansion or contraction are provided on the upper and lower surfaces of a deformation substrate 9 that is separate from the photomask substrate 1. Each of the deformation controllers 307 is bonded to the thin portion 1b of the photomask substrate 1 using, for example, a detachable adhesive material, such as an adhesive agent or an adhesive sheet, so as to be arranged, for example, in the layout illustrated in FIG. 4.

The individual deformation controller 307 adjusts a balance between stresses produced in the respective deformation members 7 and 8 provided on the deformation substrate 9 so as to be capable of selectively carrying out two deformation modes, including a first mode of producing a curvature deformation of the thin portion 1b of the photomask substrate 1, as illustrated in FIG. 13, and a second mode of not producing the curvature deformation, as illustrated in FIG. 14.

The first mode illustrated in FIG. 13 is carried out, for example, in order to control the position of the apex P of the imprint mask 2 during the convex deformation. In the first mode, in the deformation controller 307, the deformation member 7 on the deformation controller 307 that is not in contact with the thin portion 1b is given a larger expansion than the deformation member 8 that is in contact with the thin portion 1b so that the deformation controller 307 is given a deformation producing a curvature deformation of the thin portion 1b. In other words, in the first mode, the deformation controller 307 is given a deformation that gives the deformation member 7 a larger strain than that of the deformation member 8, and thereby, the deformation controller 307 is given a deformation producing a curvature deformation of the thin portion 1b. At that time, the balance of the deforming forces generated by the deformation controllers 307 arranged so as to interpose the imprint mask 2 is adjusted that the position of the apex P of the imprint mask 2 can be controlled. In the first mode, the deformation members 8 on the side in contact with the thin portion 1b need not be necessarily expanded, but may be given a contraction, or may be given neither the expansion nor the contraction.

The second mode illustrated in FIG. 14 is carried out, for example, in order to perform the higher-order distortion correction of the imprint mask 2 without producing a curvature deformation of the template 300. In the second mode, the deformation member 8 on the deformation controller 307 that is in contact with the thin portion 1b is given a larger expansion than the deformation member 7 that is not in contact with the in portion 1b so that the deformation controller 307 is given a stress producing a partial expansive or contractive deformation without producing a curvature of the in portion 1b. In other words, in the second mode, the deformation controller 307 is given a deformation that gives the deformation member 8 a larger strain than that of the deformation member 7, and thereby, the deformation controller 307 is given stress producing a partial expansive or contractive deformation without producing a curvature of the thin portion 1b. At that time, the balance of the expansive forces or the contractive forces generated by the deformation controllers 307 arranged so as to surround the imprint mask 2 is adjusted so that the higher-order correction of distortion of the imprint mask can be performed without producing a curvature deformation of the template 300. In the second mode, the deformation members 7 that are not in contact with the thin portion 1b need not be necessarily expanded, but may be given a contraction, or may be given neither the expansion nor the contraction.

For example, glass or synthetic quarts can be used for the material of the deformation substrate 9 in the same manner as in the case of the photomask substrate 1. In that case, the second mode can be carried out using the deformation member 8 that is bonded to both the thin portion 1b and the deformation substrate 9, by adjusting the cross-sectional shape of the deformation substrate 9 so that the thin portion 1b has substantially the same cross-sectional stiffness as that of the deformation substrate 9.

The third embodiment has the structure in which the deformation controllers 307 are pasted to the photomask substrate 1, so that the deformation controllers 307 can be removed from the template 300 that has reached the end of the life according to the number of times of imprinting, and can be reused for another template 300.

Other configurations, operations, and effects are the same as those of the other embodiments, so that detailed descriptions thereof are omitted here.

### Fourth Embodiment

A fourth embodiment will be described by way of an example of a configuration of electrical connections of the deformation members 7 and 8 in the above described embodiments with an external circuit (such as a controller) for driving the deformation members. Although the fourth embodiment will be described using the template 300 exemplified in the third embodiment, the description can be applied to the other embodiments in the same manner.

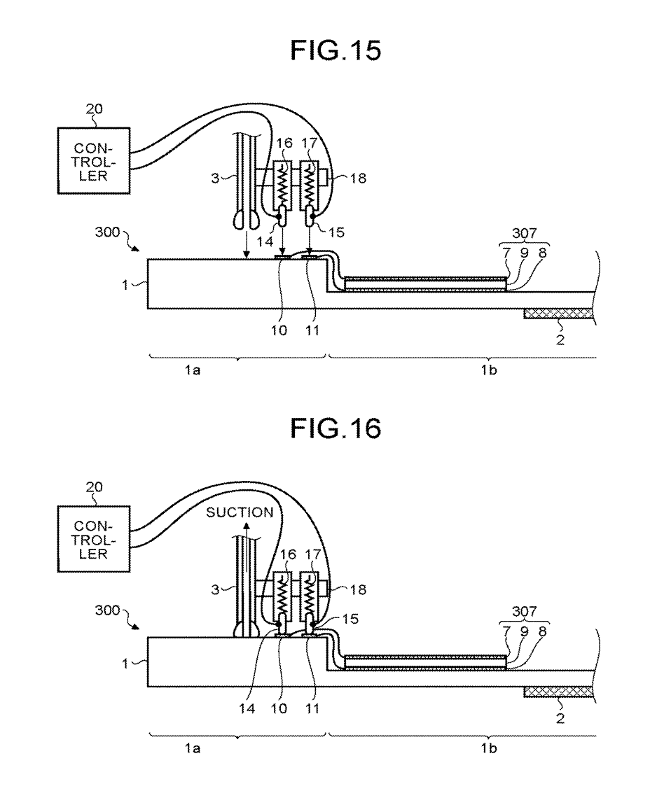

FIGS. 15 and 16 are schematic diagrams illustrating a schematic configuration example of an imprint device in the fourth embodiment, and are diagrams for explaining the configuration of the connections of the deformation members with the controller. As illustrated in FIGS. 15 and 16, terminals 10 and 11 are arranged over the upper surface of the thick portion 1a serving as the outer circumferential portion of the photomask substrate 1, and are electrically connected through wiring to the deformation members 7 and 8 of the deformation controller 307.

The circular cylindrical vacuum chuck 3 holding the template 300 by sucking the thick portion 1a of the photomask substrate 1 is provided with an arm 18 projecting toward the inside of the circular cylindrical shape. Connecting parts 14 and 15 electrically connected through wiring to a controller 20 are mounted to the arm 18 using elastic members 16 and 17. As illustrated in FIG. 15 and then in FIG. 16, when the vacuum chuck 3 is pressed onto the thick portion 1a, the elastic members 16 and 17 urge the connecting parts 14 and 15 to the terminals 10 and 11 so that electrical contact is established between each of the connecting parts and corresponding one of the terminals.

By having the configuration described above, the fourth embodiment allows the deformation members 7 and 8 provided on the template 300 to be easily connected to the external circuit, such as the controller 20. Other configurations, operations, and effects are the same as those of the other embodiments, so that detailed descriptions thereof are omitted here.

As described above, in the above-described embodiments, for example, piezoelectric thin films can be used as the deformation members 7 and 8 that deform the thin portion 1b of the photomask substrate 1 provided with the imprint mask 2. The piezoelectric thin films can be formed on the photomask substrate 1 and the deformation substrate 9, for example, by film forming using a semiconductor process or patterning using an inkjet system. A bulk piezoelectric thin film in a film shape can also be used as the deformation members 7 and 8. In that case, the bulk piezoelectric thin film is bonded to the photomask substrate 1 and/or the deformation substrate 9 using, for example, a detachable adhesive material, such as an adhesive agent or an adhesive sheet.

In general, a piezoelectric element has a property called hysteresis that exhibits nonlinearity in deformation in the reverse direction when the expansion and the contraction are electrically controlled. For this reason, if the piezoelectric thin films are used for the deformation members 7 and 8, the hysteresis of the deformation members 7 and 8 needs to be taken into account the curvature deformation or distortional deformation of the template is controlled. Accordingly, in the embodiments described above, correspondence relations between voltage values applied to the deformation members 7 and 8 and amounts of deformation (amounts of curvature deformation and distortional deformation) of the template at that time may be identified by experiment, simulation, or the like, and the deformation of the template may be controlled by controlling the voltages applied to the deformation members 7 and 8 based on the correspondence relations thus identified. In that case, the identified correspondence relations may be used to establish in advance a database or a control law for the control.

While certain embodiments have been described, these embodiments have been presented by way of example only, and are not intended limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template for imprinting, configured to be pressed onto a semiconductor wafer to transfer thereto a pattern, the template comprising:
an imprint mask on which the pattern is formed;
a mask substrate on which the imprint mask is provided; and
a plurality of deformation controllers that are provided at the mask substrate outside a circumference of the imprint mask, and are configured to deform the mask substrate.

2. The template according to claim 1, wherein
the imprint mask is provided on a first surface of the mask substrate, and
each of the deformation controllers comprises a first deformation member that is provided on a second surface on the opposite side of the first surface of the mask substrate, and is configured to deform the mask substrate by expanding or contracting.

3. The template according to claim 2, wherein each of the deformation controllers further comprises a second deformation member that is provided on the first surface of the mask substrate outside the circumference of the imprint mask so as to form a pair with the first deformation member, and is configured to deform the mask substrate by expanding or contracting.

4. The template according to claim 1, wherein
each of the deformation controllers comprises:
a plate-like deformation substrate;
a first deformation member provided on a first surface of the deformation substrate; and
a second deformation member provided on a second surface on the opposite side of the first surface of the deformation substrate, and
a fourth surface of the second deformation member on the opposite side of a third surface of the second deformation member in contact with the deformation substrate is bonded to the mask substrate so that each of the deformation controllers is bonded to the mask substrate.

5. The template according to claim 4, wherein the deformation substrate has the same cross-sectional stiffness as that at a portion of the mask substrate provided with each of the deformation controllers.

6. The template according to claim 1, wherein
the mask substrate comprises a thin portion obtained by thinning a central portion of the mask substrate into a counterbore structure and a thick portion located outside a circumference of the thin portion, and
the deformation controllers are provided at the thin portion outside the circumference of the imprint mask.

7. The template according to claim 1, wherein each of the deformation members comprises a piezoelectric thin film.

8. The template according to claim 1, wherein the deformation controllers are fixed with a detachable adhesive material to the mask substrate outside a circumference of the imprint mask.

9. An imprint device comprising:
the template as claimed in claim 1;
a vacuum chuck having a circular cylindrical shape, the vacuum chuck being configured to hold the template by sucking an outer circumferential portion of the mask substrate; and
a controller configured to control the deformation controllers, wherein
the template comprises:
a plurality of terminals that are provided at the mask substrate outside a circumference of the deformation controllers, and are electrically connected to any of the deformation controllers; and
a plurality of connecting parts that are provided inside the circular cylindrical shape of the vacuum chuck, that are come into contact with the terminals when the vacuum chuck abuts on the mask substrate, and that are electrically connected to the controller.

10. The imprint device according to claim 9, wherein
the imprint mask is provided on a first surface of the mask substrate,
each of the deformation controllers comprises:
a first deformation member that is provided on a second surface on the opposite side of the first surface of the mask substrate, and is configured to deform the mask substrate by expanding or contracting; and
a second deformation member that is provided on the first surface of the mask substrate outside the circumference of the imprint mask so as to form a pair with the first deformation member, and is configured to deform the mask substrate by expanding or contracting, and
the controller is configured to apply substantially the same amount of expansion or contraction to the first and the second deformation members forming a pair with the mask substrate interposed therebetween among the first deformation members and the second deformation members arranged on the first surface and the second surface of the mask substrate so as to surround the imprint mask, and to thereby give the mask substrate a partial expansive or contractive deformation without producing a curvature of the mask substrate.

11. The imprint device according to claim 9, wherein the controller is configured to give the first and the second deformation members forming a second pair that are arranged opposite to the first and the second deformation members forming a first pair with the imprint mask interposed therebetween a larger amount of expansion or contraction than that given to the first and the second deformation members forming the first pair, and to thereby give the mask substrate a partial expansive or contractive deformation without producing a curvature deformation of the mask substrate.

12. The imprint device according to claim 9, wherein
each of the deformation controllers comprises:
a plate-like deformation substrate;
a first deformation member provided on a first surface of the deformation substrate; and
a second deformation member provided a second surface on the opposite side of the first surface of the deformation substrate,
a fourth surface of the second deformation member on the opposite side of a third surface of the second deformation member in contact with the deformation substrate is bonded to the mask substrate so that each of the deformation controllers is bonded to the mask substrate, and
the controller is configured to give each of the deformation controllers a deformation that gives the first, deformation member a larger strain than that of the second deformation member so as to give the mask substrate a curvature deformation.

13. The imprint device according to claim 9, wherein
each of the deformation controllers comprises:
a plate-like deformation substrate;
a first deformation member provided on a first surface of the deformation substrate; and
a second deformation member provided on a second surface on the opposite side of the first surface of the deformation substrate,
a fourth surface of the second deformation member on the opposite side of a third surface of the second deformation member in contact with the deformation substrate is bonded to the mask substrate so that each of the deformation controllers is bonded to the mask substrate, and
the controller is configured to give each of the deformation controllers a deformation that gives the second deformation member a larger strain than that of the first deformation member so as to give the mask substrate a partial expansive or contractive deformation without producing a curvature of the mask substrate.

14. A control method for controlling deformation of the template according to claim 1, the control method comprising:
identifying correspondence relations between voltage values of voltages applied to the deformation controllers and amounts of deformation of the template at the time of application of the voltages; and
controlling the deformation of the template based on the identified correspondence relations.
